(19) United States
(12) Patent Application Publication
(10) Pub. No.: US 2008/0128904 A1
(43) Pub. Date: Jun. 5, 2008

(54) Semiconductor device and method of manufacturing semiconductor device

(75) Inventor: Tatsuya Sakamoto, Fukuoka (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 11/946,428

(22) Filed: Nov. 28, 2007

(30) Foreign Application Priority Data
Dec. 1, 2006 (JP) 2006-326385

(51) Int. Cl. H01L 23/48; H01L 21/50

(52) U.S. Cl. 257/737; 438/113; 257/E23.01; 257/E21.499

(57) ABSTRACT

A semiconductor device according to the present invention includes a semiconductor chip having an interlayer film provided with an electrode for external connection in a prescribed position, rewiring conducting to the electrode and provided on the interlayer film, an insulating layer covering the rewiring, a pad conducting to the rewiring through an opening formed in the insulating layer and a solder terminal provided on the pad. A photosensitive resin film is provided on the insulating layer. The photosensitive resin film covers the peripheral edge of the interlayer film.

### BACKGROUND OF THE INVENTION

1. Field of the Invention

The present invention relates to a semiconductor device and a method of manufacturing a semiconductor device, and more particularly, it relates to a semiconductor device which is a so-called wafer-level CSP and a method of manufacturing the semiconductor device.

2. Description of Related Art

In order to satisfy the requirement for downsizing of a semiconductor device, a semiconductor device referred to as a wafer-level CSP (chip scale package) has been employed recently.

In the wafer-level CSP (hereinafter referred to as “WL-CSP”), a structure having the function of a package is formed on a wafer before the wafer is cut (diced). Then, the wafer is directly diced into the semiconductor device mountable on a mounting substrate. The WL-CSP is provided with no conventional container-type structure generally called as a package, so that it can be downsized accordingly.

In a process of manufacturing the WL-CSP, a desired semiconductor circuit is formed on each semiconductor chip forming region of the wafer divided along scribe lines according to a general process of manufacturing a semiconductor chip. Further, an electrode employed for inputting/outputting a signal in/from the semiconductor circuit or applying a driving voltage or a ground voltage thereto is formed on each semiconductor chip forming region.

The electrode electrically connected with an external wire is preferably arranged on a planar surface. Therefore, a so-called interlayer film is formed on the upper surface of the wafer by an oxide film or the like, and the upper surface of this interlayer film is planarized by CMP (chemical mechanical polishing).

The electrode is formed as a so-called embedded electrode formed by penetratingly embedding a metallic material in a prescribed position of the interlayer film. This embedded electrode itself is hereinafter simply referred to as “electrode”. A pad-type metal film may be connected with an end of the embedded electrode in some cases. In such a case, the embedded electrode including the pad-type metal film is simply referred to as “electrode”.

In a semiconductor device employing a general package, a wafer is diced along scribe lines after formation of an electrode. In the WL-CSP, on the other hand, rewiring electrically connected with the electrode is formed on the interlayer film after formation of the electrode. The rewiring is thereafter insulated and covered with an insulating layer and an opening is formed in a prescribed position of the insulating layer, thereby forming a connecting portion partially exposing the rewiring through the opening. Further, a molding layer is formed by covering the upper surface of the insulating layer with molding resin, and an opening for exposing the connecting portion is formed in a prescribed position of the molding layer. A post electrically connected with the rewiring is provided in the opening of the molding layer, a solder terminal is mounted on the post, and the wafer is thereafter diced along the scribe lines.

In this dicing, not only a semiconductor substrate constituting the wafer but also the interlayer film, the insulating layer and the molding layer are cut, whereby the interlayer film and the insulating layer are exposed on the cut end surface formed by the cutting.

When exposed on the cut end surface, the interlayer film is easily separated from the semiconductor substrate.

In a recent WL-CSP, therefore, rewiring 120 is provided on a wafer 100 having an interlayer film 110 and an electrode, an insulating layer 130 including a passivation film 130a such as a silicon nitride film and a buffer film 130b such as a polyimide film is formed, and a trench 160 is thereafter formed by cutting a wafer 100 in half along a scribe line using a wide dicing blade, as shown in FIG. 9. Then, a molding layer 210, a post 220 and a solder terminal 230 are successively formed, and the wafer 100 is thereafter diced along the trench 160. Referring to FIG. 9, a numeral 200 denotes a cutting groove formed by this dicing.

When the trench 160 is formed in the interlayer film 110 by cutting the wafer 100 in half along the scribe line, the outer trench 160 is backfilled with the molding layer 210, whereby the periphery of the interlayer film 110 is covered with the molding layer 210. Consequently, the interlayer film 110 can be prevented from being exposed on the cut end surface after the dicing, and thus inhibited from being separated.

With further increase in the requirement for downsizing of the semiconductor device, however, a thin WL-CSP provided with no molding layer is desired. If no molding layer is provided, rewiring 120 is provided on a wafer 100 having an interlayer film 110 and an electrode, an insulating layer 130 including a passivation film 130a such as a silicon nitride film and a buffer film 130b such as a polyimide film is formed, and an opening is thereafter formed in a prescribed position of the insulating layer 130, as shown in FIG. 10. Then, a pad 150 electrically connected with the rewiring 120 is formed, a solder terminal 190 is formed on the pad 150, and the wafer 100 is thereafter diced along scribe lines. Therefore, the interlayer film 110 is exposed on the cut end surface formed by the dicing.

In particular, when such a thin WL-CSP is mounted on a necessary substrate 300, the space between the thin WL-CSP and the substrate 300 is filled up with a bonding assistant referred to as an underfiller 400, as shown in FIG. 11. Therefore, stress caused by contraction of the underfiller 400 resulting from hardening thereof acts on the interlayer film 110, to increase the rate of separation of the interlayer film 110 from a semiconductor device 100′. Referring to FIG. 11, a numeral 310 denotes a connecting pad provided on the substrate 300.

### SUMMARY OF THE INVENTION

One aspect of the present invention may provide a semiconductor device including: a semiconductor chip having an interlayer film provided with an electrode for external connection on a prescribed position; rewiring conducting to the electrode and provided on the interlayer film; an insulating layer covering the rewiring; a pad conducting to the rewiring through an opening formed in the insulating layer; and a solder terminal provided on the pad, wherein a photosensitive resin film is provided on the insulating layer, and the peripheral edge of the interlayer film is covered with the photosensitive resin film.

According to this structure, the interlayer film can be prevented from being exposed, and thus inhibited from being separated from a semiconductor substrate constituting the semiconductor chip. In particular, the photosensitive resin film can be relatively reduced in thickness, whereby the peripheral edge of the interlayer film can be covered by the photosensitive resin film without increasing the size of the semiconductor device as a result of formation of the photosensitive resin film.

A step may be provided on the outer periphery of the semiconductor chip by protruding the peripheral edge of the rear side thereof opposite to the interlayer film outward beyond the peripheral edge closer to the interlayer film, and the peripheral edge of the semiconductor chip closer to the interlayer film may be covered with the photosensitive resin film.

Thus, the photosensitive resin film covering the peripheral edge of the interlayer film can be prevented from being separated from the semiconductor substrate constituting the semiconductor chip.

Preferably, the thickness of the photosensitive resin film covering the peripheral edge of the semiconductor chip closer to the interlayer film is smaller than the protrusion amount of the peripheral edge of the rear side thereof opposite to the interlayer film.

Thus, the photosensitive resin film can be prevented from being broken when a wafer is cut by dicing, and the photosensitive resin film can be prevented from being separated from the semiconductor substrate resulting from breakage thereof.

Preferably, the height of the upper surface of the photosensitive resin film is rendered so as to be smaller than the height of the upper surface of the pad, so that the pad protrudes from the photosensitive resin film.

Thus, although the photosensitive resin film is provided, the pad and the solder terminal can be excellently connected with each other, and the possibility of reduction in the reliability of the semiconductor device can be eliminated.

Another aspect of the present invention may provide a method of manufacturing a semiconductor device including an interlayer film provided on each semiconductor chip forming region of a wafer divided along a scribe line, rewiring provided on the interlayer film and connected with an electrode for external connection provided on the semiconductor chip and a pad electrically connected with a prescribed position of the rewiring. This method of manufacturing a semiconductor device includes the steps of: forming a trench in the wafer along the scribe line after formation of the pad; forming a photosensitive resin film on the wafer provided with the trench; patterning the photosensitive resin film to form an opening in the photosensitive resin film located on the pad; reducing the thickness of the photosensitive resin film by ashing; forming a solder terminal on the pad; and dicing the wafer by forming in the trench a cutting groove smaller in width than the trench.

According to this manufacturing method, the peripheral edge of the interlayer film is covered with the photosensitive resin film, whereby the interlayer film can be prevented from being exposed, and inhibited from being separated from a semiconductor substrate constituting the semiconductor chip.

Preferably, portions of the photosensitive resin film is removed from the pad and from the trench and an etching groove of the photosensitive resin film smaller in width than the trench and larger in width than the cutting groove is formed in the trench in the step of patterning the photosensitive resin film, and the cutting groove is formed in the etching groove in the dicing step.

Thus, the photosensitive resin film is not cut when the wafer is cut by dicing, the possibility for breakage of the photosensitive resin film is eliminated, and the photosensitive resin film can be prevented from being separated from the semiconductor substrate resulting from breakage thereof.

The above-described and other objects, features and effects of the present invention can be made apparent based on the following description of embodiments with reference to the accompanying drawings.

### BRIEF DESCRIPTION OF THE DRAWINGS

FIG. 1 is a fragmented schematic sectional view showing a principal part of a semiconductor device according to an embodiment of the present invention.

FIG. 2 is a fragmented schematic sectional view for illustrating the step of manufacturing a semiconductor device.

FIG. 3 is a fragmented schematic sectional view for illustrating the step of manufacturing a semiconductor device.

FIG. 4 is a fragmented schematic sectional view for illustrating the step of manufacturing a semiconductor device.

FIG. 5 is a fragmented schematic sectional view for illustrating the step of manufacturing a semiconductor device.

FIG. 6 is a fragmented schematic sectional view for illustrating the step of manufacturing a semiconductor device.

FIG. 7 is a fragmented schematic sectional view for illustrating the step of manufacturing a semiconductor device.

FIG. 8 is a fragmented schematic sectional view for illustrating the step of manufacturing a semiconductor device.

FIG. 9 is a fragmented schematic sectional view showing a principal part of a conventional semiconductor device.

FIG. 10 is a fragmented schematic sectional view showing a principal part of another conventional semiconductor device.

FIG. 11 is a fragmented schematic sectional view of a principal part of the conventional semiconductor device mounted on a mounting substrate.

### DETAILED DESCRIPTION OF PREFERRED EMBODIMENTS

An embodiment of the present invention is now described in detail with reference to the drawings.

FIG. 1 is a schematic sectional view of a principal part of a semiconductor device according to this embodiment.

The semiconductor device A is formed in the state of a wafer which is a discoid semiconductor substrate. The base of semiconductor device A is a semiconductor substrate rectangularly formed in plan view by dicing a wafer, as described later.

A necessary semiconductor circuit (not shown) is formed on the semiconductor substrate by a known semiconductor circuit forming technique. The semiconductor substrate provided with the semiconductor circuit is hereinafter referred to as a semiconductor chip 10′, for the convenience of illustration.

An interlayer film 11 formed by an oxide film, for example, is provided on the upper surface of the semiconductor chip 10′. An unshown electrode is provided on a prescribed position of the interlayer film 11. A signal is input into or output from the semiconductor circuit or a driving voltage or a ground voltage is applied to the semiconductor circuit through this electrode.

Rewiring 12 electrically connected with the electrode is provided on the interlayer film 11. Further, an insulating layer 13 including a passivation film 13a such as a silicon nitride film covering the rewiring 12 and a buffer film 13b such as a polyimide film is provided on the interlayer film 11. The passivation film 13a is provided basically for the purpose of insulation. The buffer film 13b is provided for the purpose of stress relaxation.

An opening is formed in a prescribed position of the insulating layer 13. A pad 15 electrically connected with the rewiring 12 is provided in this opening.

A photosensitive resin film 17 is provided on the buffer film 13b. The photosensitive resin film 17 covers the interlayer film 11, the passivation film 13a and the buffer film 13b while exposing the pad 15.

A step 10′a is formed on the outer periphery of the semiconductor chip 10′ by protruding the peripheral edge of the rear side thereof opposite to the interlayer film 11 outward beyond the peripheral edge closer to the interlayer film 11. The photosensitive resin film 17 reaches the step 10′a along the side surfaces of the insulating layer 13 and the interlayer film 11. Thus, the peripheral edge of the interlayer film 11 is reliably covered with the photosensitive resin film 17.

The photosensitive resin film 17 covers the peripheral edge of the interlayer film 11 in the aforementioned manner, whereby the interlayer film 11 can be prevented from being exposed and inhibited from being separated from the semiconductor chip 10′.

A thickness L1 of the photosensitive resin film 17 covering the peripheral edge of the semiconductor chip 10′ closer to the interlayer film 11 is smaller than a protrusion amount L2 of the peripheral edge of the rear side of the semiconductor chip 10′ opposite to the interlayer film 11. When the wafer is divided into each semiconductor chip 10′ by dicing, therefore, there is no possibility of a dicing blade coming into contact with and breaking the photosensitive resin film 17. Thus, the photosensitive resin film 17 can be prevented from being separated resulting from breakage.

A solder terminal 19 made of solder is provided on the pad 15 exposed from the photosensitive resin film 17. The height of the upper surface of the photosensitive resin film 17 is smaller than that of the upper surface of the pad 15, and the pad 15 protrudes from the photosensitive resin 17. Therefore, the pad 15 and the solder terminal 19 can be excellently connected with each other.

The solder terminal 19 is a so-called solder ball. A solder ball having a prescribed grain diameter may be welded to the pad 15 to form the solder terminal 19, or a solder film may be formed by applying solder paste or by solder plating and thereafter melted by heating to form the ball-shaped solder terminal 19.

A method of manufacturing a semiconductor device according to this embodiment is now described.

The semiconductor device is manufactured in the state of a wafer. A prescribed semiconductor circuit is formed by a known semiconductor manufacturing technique on each of semiconductor chip forming regions to be divided along scribe lines provided on a wafer-state semiconductor substrate in a grid form.

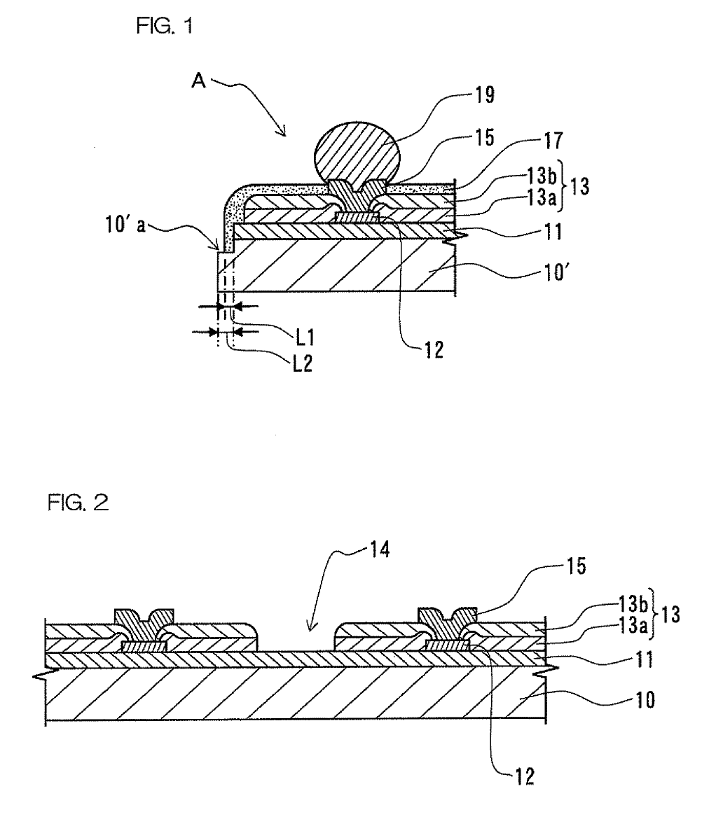

After the formation of the semiconductor circuit, an interlayer film 11 constituted of an insulating film such as an oxide film is formed on the upper surface of the wafer 10 provided with the semiconductor circuit, as shown in FIG. 2. The interlayer film 11 is formed in a prescribed thickness by a proper film forming technique such as CVD (chemical vapor deposition), and thereafter planarized by CMP. However, the interlayer film 11 may not necessarily be planarized, but such planarization may be performed if necessary.

Before the planarization, an electrode (not shown) for the semiconductor circuit for external connection is embedded in a prescribed position of the interlayer film 11. A resist mask is formed on the upper surface of the interlayer film 11 and then the interlayer film 11 is etched, thereby forming an opening for forming the electrode in the prescribed position of the interlayer film 11. Thereafter a metal film is formed on the upper surface of the interlayer film 11 by sputtering or the like and the opening for forming the electrode is filled up with the metal, whereby the electrode is formed in this opening. After the formation of the metal film, the interlayer film 11 is planarized by CMP, while the metal film is scraped off along with the interlayer film 11.

After the formation of the interlayer film 11 provided with the electrode in the prescribed position, another metal film is formed on the upper surface of the interlayer film 11 by sputtering or the like and thereafter patterned in a prescribed manner, thereby forming rewiring 12 electrically connected with the electrode. According to this embodiment, the rewiring 12 is made of aluminum.

After the formation of the rewiring 12, a passivation film 13a constituted of a silicon nitride film is formed on the upper surface of the wafer 10 by CVD. The passivation film 13a is not limited to the silicon nitride film, but may be formed by a proper insulating film. After the formation of the passivation film 13a, the passivation film 13a is patterned, so that an opening partially exposing the rewiring 12 is formed in a position for arranging a solder terminal described later. In this patterning, a portion of the passivation film 13a is removed from a scribe line region 14 of the wafer 10.

After the formation of the passivation film 13a, a buffer film 13b such as a polyimide film is formed on the upper surface of the wafer 10 by spin coating or the like. The buffer film 13b is not limited to the polyimide film, but may be formed by a proper insulating film. After the formation of the buffer film 13b, the buffer film 13b is patterned, so that an opening communicating with the opening provided in the passivation film 13a is formed. As a result, a portion of the rewiring 12 is exposed. In this patterning, a portion of the buffer film 13b is removed from the scribe line region 14 of the wafer 10. According to this embodiment, the passivation film 13a and the buffer film 13b constitute an insulating layer 13.

After the formation of the buffer film 13b, a metal film is formed on the upper surface of the wafer 10 by sputtering or the like and patterned, so that a pad 15 is formed in the position for forming the solder terminal described later. The pad 15 is provided in the openings formed in the passivation film 13a and the buffer film 13b, and electrically connected with the rewiring 12. According to this embodiment, the pad 15 is made of copper.

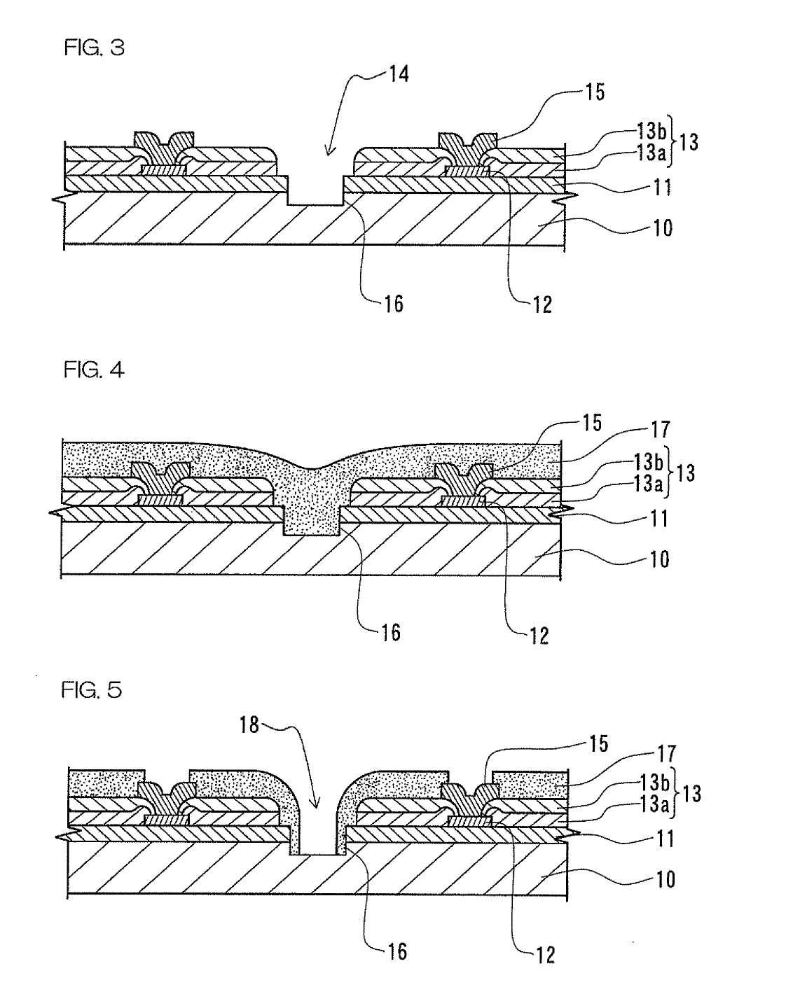

After the formation of the pad 15, the wafer 10 is cut in half along a scribe line with a wide dicing blade, so that a trench 16 is formed in the wafer 10 along the scribe line, as shown in FIG. 3. This trench 16 is formed in a depth with which the interlayer film 11 is completely cut along the scribe line. The depth of the trench 16 is preferably decided so that the wafer 10 is not broken along the trench 16 when the wafer 10 is handled, and generally set within 50% of the thickness of the wafer 10.

After the formation of the trench 16, a photosensitive resin film 17 covering the pad 15 is formed by applying photosensitive resin to the wafer 10, as shown in FIG. 4. Polyimide or polybenzoxazole can be employed as the photosensitive resin.

After the formation of the photosensitive resin film 17, an opening is formed in the portion of the photosensitive resin film 17 located on the pad 15 by patterning the photosensitive film 17, as shown in FIG. 5. The pad 15 is exposed from the photosensitive resin film 17 through this opening. At this time, the photosensitive resin film 17 can be extremely easily patterned by curing the photosensitive resin on the basis of exposure by known photolithography and removing an unexposed portion by etching.

When the photosensitive resin film 17 is patterned, not only the portion located on the pad 15 but also the portion located in the trench 16 is patterned and removed along the trench 16, whereby an etching groove 18 of the photosensitive resin film 17 is formed in the trench 16. This etching groove 18 is smaller in width than the trench 16 formed in the wafer 10. Further, the etching groove 18 is larger in width than a cutting groove 20 to be formed in the wafer 10 with a dicing blade described later employed for dicing the wafer 10 (see FIG. 8).

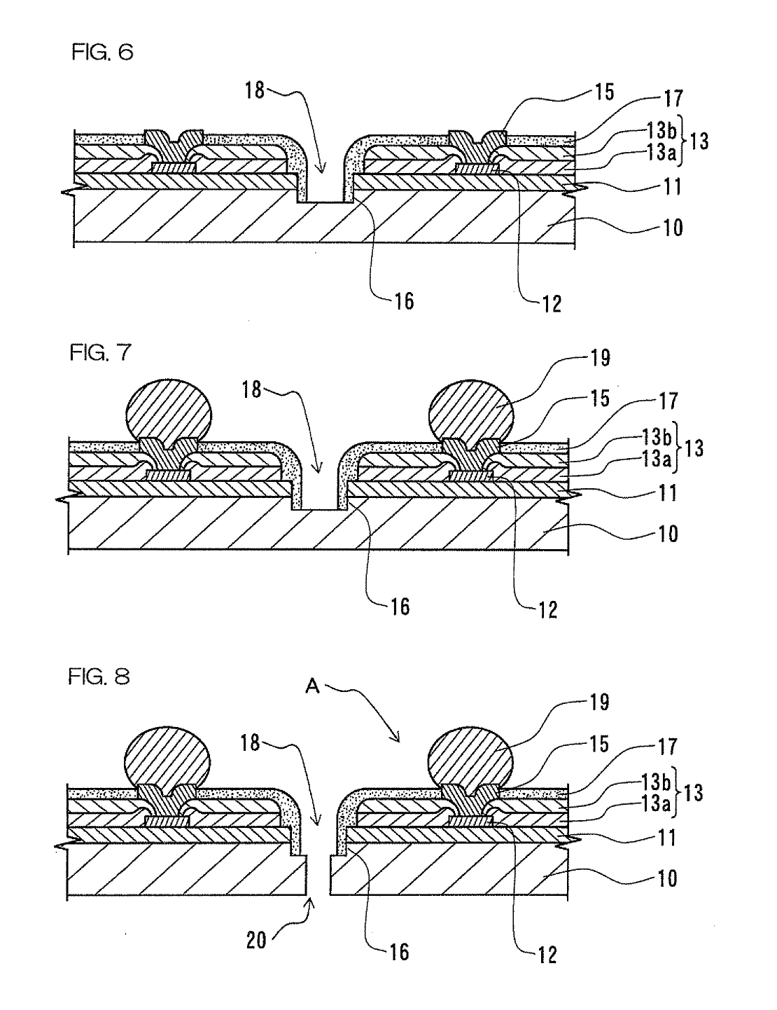

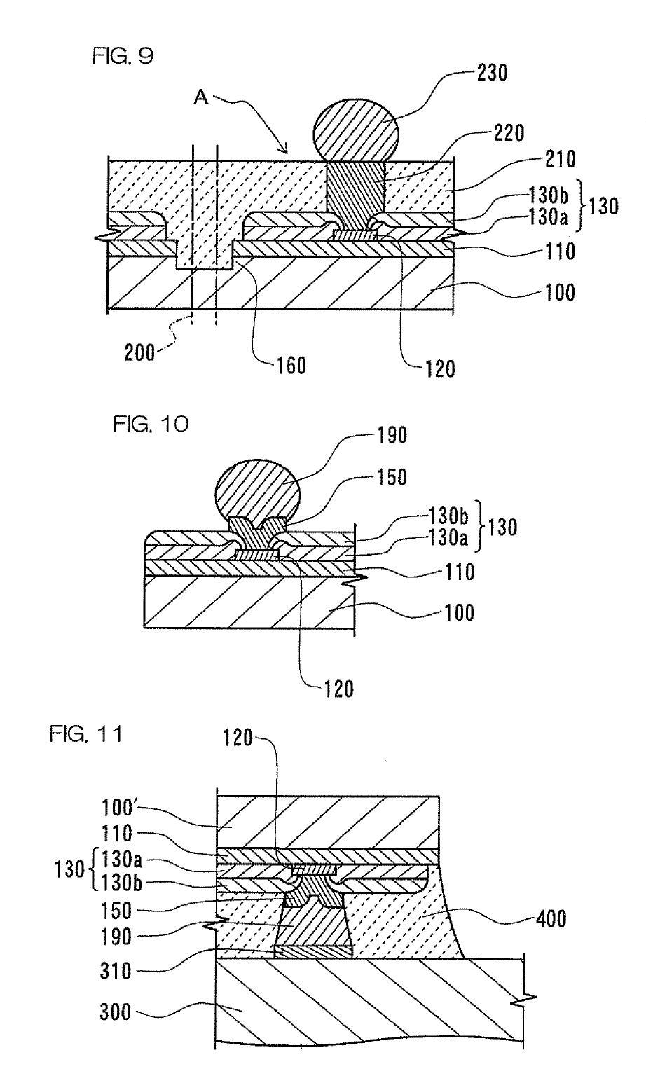

After the patterning of the photosensitive resin film 17, the photosensitive resin film 17 is reduced in thickness by ashing. The time for this ashing is set so that the upper surface of the photosensitive resin film 17 is lower than that of the pad 15 and the pad 15 protrudes from the photosensitive resin film 17, as shown in FIG. 6.

Since the pad 15 thus protrudes from the photosensitive resin film 17, a solder terminal 19 can be improved in connection strength and long-term reliability when the solder terminal 19 is mounted on the pad 15 as described later (see FIG. 7).

The etching groove 18 formed in the photosensitive resin film 17 may be rendered smaller in width than the trench 16 formed in the wafer 10 and larger in width than the cutting groove 20 to be formed in the wafer 10 in consideration of the reduction in the thickness of the photosensitive resin film 17 resulting from the ashing.

After the photosensitive resin film 17 is reduced in thickness by the ashing, the solder terminal 19 is formed on the pad 15, as shown in FIG. 7. According to this embodiment, the solder terminal 19 is formed by mounting a solder ball having a prescribed grain diameter on each pad 15, melting this solder ball and welding the same to the pad 15. Alternatively, the solder terminal 19 may be formed by applying solder paste to the pad 15 or providing a solder film on the pad 15 by solder plating.

After the formation of the solder terminal 19, the wafer 10 is diced along the trench 16 provided therein, so that an individually separated semiconductor device A is obtained as shown in FIG. 8.

In order to dice the wafer 10, a blade smaller in width than the etching groove 18 is employed. The etching groove 18 is cut with such a blade, so that the cutting groove 20 is formed in the etching groove 18.

Thus, the semiconductor device A including the interlayer film 11 having the peripheral edge covered with the photosensitive resin film 17 can be extremely easily manufactured by forming in the wafer 10 the trench 16 for cutting the interlayer film 11 along the scribe line, backfilling this trench 16 with the photosensitive resin film 17, forming the cutting groove 20 smaller in width than the trench 16 in the trench 16 and dicing the wafer 10. The interlayer film 11 can be inhibited by the photosensitive resin film 17 from being separated from the semiconductor substrate constituting the semiconductor chip 10′.

In particular, the peripheral edge of the interlayer film 11 is covered with the photosensitive resin film 17, whereby the peripheral edge of the interlayer film 11 can be reliably covered without increasing the size of the semiconductor device A.

Further, the cutting groove 20 is formed in the etching groove 18, so that the photosensitive resin film 17 is not broken when the wafer 10 is cut by dicing. Consequently, the photosensitive resin film 17 can be prevented from being separated from the semiconductor substrate resulting from breakage thereof.

In addition, the trench 16 is formed in the wafer 10 along the scribe line and the cutting groove 20 smaller in width than the trench 16 is formed in the trench 16, whereby the step 10′a is formed on the outer periphery of the diced semiconductor device A. The etching groove 18 smaller in width than the trench 16 and larger in width than the cutting groove 20 is formed in the trench 16 and the cutting groove 20 is formed in this etching groove 18, whereby the thickness L1 of the photosensitive resin film 17 covering the peripheral edge of the semiconductor chip 10′ closer to the interlayer film 11 can be rendered smaller than the protrusion amount L2 of the peripheral edge of the rear side opposite to the interlayer film 11.

A detailed description has been given of embodiments of the present invention. However, these embodiments are only specific examples used to make apparent the technical features of the present invention, and the present invention should not be interpreted as being limited to these specific examples, and the spirit and the scope of the present invention are limited only by the scope of the appended claims.

The present application corresponds to Japanese Patent Application No. 2006-326385 filed with the Japan Patent Office on Dec. 1, 2006, and all the disclosures thereof are incorporated herein by references.

What is claimed is:

1. A semiconductor device comprising:
a semiconductor chip having an interlayer film provided with an electrode for external connection on a prescribed position;
rewiring conducting to the electrode and provided on the interlayer film;
an insulating layer covering the rewiring;
a pad conducting to the rewiring through an opening formed in the insulating layer; and
a solder terminal provided on the pad, wherein
a photosensitive resin film is provided on the insulating layer, and a peripheral edge of the interlayer film is covered with the photosensitive resin film.

2. The semiconductor device according to claim 1, wherein
a step is provided on a outer periphery of the semiconductor chip by protruding a peripheral edge of a rear side of the semiconductor chip opposite to the interlayer film outward beyond a peripheral edge of the semiconductor chip closer to the interlayer film, and
the peripheral edge of the semiconductor chip closer to the interlayer film is covered with the photosensitive resin film.

3. The semiconductor device according to claim 2, wherein
a thickness of the photosensitive resin film covering the peripheral edge of the semiconductor chip closer to the interlayer film is smaller than a protrusive amount of the peripheral edge of the rear side thereof opposite to the interlayer film.

4. The semiconductor device according to claim 1, wherein
a height of an upper surface of the photosensitive resin film is rendered smaller than a height of an upper surface of the pad, so that the pad protrudes from the photosensitive resin film.

5. A method of manufacturing a semiconductor device comprising an interlayer film provided on each semiconductor chip forming region of a wafer divided along a scribe line, rewiring provided on the interlayer film and connected with an electrode for external connection provided on the semiconductor chip and a pad electrically connected with a prescribed position of the rewiring, comprising the steps of:
forming a trench in the wafer along the scribe line after formation of the pad;
forming a photosensitive resin film on the wafer provided with the trench;
patterning the photosensitive resin film to form an opening in the photosensitive resin film located on the pad;
reducing a thickness of the photosensitive resin film by ashing;
forming a solder terminal on the pad; and
dicing the wafer by forming in the trench a cutting groove smaller in width than the trench.

6. The method of manufacturing a semiconductor device according to claim 5, wherein
portions of the photosensitive resin film is removed from the pad and from the trench and an etching groove of the photosensitive resin film smaller in width than the trench and larger in width than the cutting groove is formed in the trench in the step of patterning the photosensitive resin film, and
the cutting groove is formed in the etching groove in the dicing step.
